(19) United States
(12) Patent Application Publication
(10) Pub. No.: US 2026/0005037 A1
(43) Pub. Date: Jan. 1, 2026

(54) METHOD FOR REINFORCING BONDED WAFER

(71) Applicant: SHANGHAI SIMWINGS TECHNOLOGY CO., LTD, Shanghai (CN)

(72) Inventors: Ziwen WANG, Shanghai (CN); Wei ZHU, Shanghai (CN); Xing WEI, Shanghai (CN); Wei LI, Shanghai (CN)

(21) Appl. No.: 19/252,772

(22) Filed: Jun. 27, 2025

(30) Foreign Application Priority Data
Jun. 27, 2024 (CN) 202410852672.9

(51) Int. Cl. H01L 21/324; H01L 21/304; H01L 21/306; H01L 21/311

(52) U.S. Cl. CPC H01L 21/324; H01L 21/304; H01L 21/30604; H01L 21/31111

(57) ABSTRACT

The present invention provides a method for reinforcing a bonded wafer, which includes: providing the bonded wafer, which includes a substrate layer, a top silicon layer and an insulating buried oxide layer; performing a first thermal reinforcing process on the bonded wafer; performing an edge grinding process on an unbonded region along the periphery of the top silicon layer; and performing a second thermal reinforcing process on the bonded wafer at a temperature higher than a temperature at which the first thermal reinforcing process is performed.

### CROSS-REFERENCES TO RELATED APPLICATION

This application claims the priority of Chinese patent application number 202410852672.9, filed on Jun. 27, 2024 and entitled “METHOD FOR REINFORCING BONDED WAFER”, the entire contents of which are incorporated herein by reference.

### TECHNICAL FIELD

The present invention relates to the field of semiconductor technology and, in particular, to a method for reinforcing a bonded wafer.

### BACKGROUND

The rapid development of integrated circuit (IC) technology and the ever-ongoing IC process node evolution have significantly raised the cost of IC fabrication and design and brought about a trend of decreasing yield and productivity. The use of bulk silicon substrates is considered as one of the important factors that limit the development of IC technology. In contrast, silicon-on-insulator (SOI) substrates are being increasingly used due to their advantages over bulk silicon substrates, including less parasitic capacitance, reduced short-channel effect, higher integration density, faster speed and lower power dissipation. However, the manufacturing of SOI wafers suffers from low yield, which is particularly attributable to slip lines. The generation and extension of slip lines in a SOI wafer may cause deformation of the wafer, which may in turn lead to degradation in electrical performance or even failure of devices formed thereon. These severely threaten the yield of products manufactured from SOI wafers.

### SUMMARY

It is an object of the present invention to provide a method for reinforcing a bonded wafer, which can reduce the generation of slip lines in the bonded wafer and improve yield of products manufactured from the bonded wafer.

To this end, the present invention provides a method for reinforcing a bonded wafer, which includes:
providing the bonded wafer, which includes a substrate layer, a top silicon layer and an insulating buried oxide layer;
performing a first thermal reinforcing process on the bonded wafer;
performing an edge grinding process on an unbonded region along the periphery of the top silicon layer; and
performing a second thermal reinforcing process on the bonded wafer at a temperature higher than a temperature at which the first thermal reinforcing process is performed.

Optionally, the temperature at which the first thermal reinforcing process is performed is lower than or equal to 1000° C.

Optionally, the temperature at which the first thermal reinforcing process is performed ranges from 850° C. to 1000° C.

Optionally, the first thermal reinforcing process may be performed for a period of time ranging from 30 min to 120 min.

Optionally, the temperature at which the second thermal reinforcing process is performed is higher than 1000° C.

Optionally, the temperature at which the second thermal reinforcing process is performed ranges from 1100° C. to 1300° C.

Optionally, the second thermal reinforcing process may be performed for a period of time ranging from 30 min to 150 min.

Optionally, each of the first and second thermal reinforcing processes are respectively performed in an oxygen-containing or hydrogen-containing inert atmosphere.

The present invention provides a method for reinforcing a bonded wafer, including: providing the bonded wafer, which includes a substrate layer, a top silicon layer and an insulating buried oxide layer; performing a first thermal reinforcing process on the bonded wafer; performing an edge grinding process on an unbonded region along the periphery of the top silicon layer; and performing a second thermal reinforcing process on the bonded wafer at a temperature higher than a temperature at which the first thermal reinforcing process is performed.

### BRIEF DESCRIPTION OF THE DRAWINGS

FIG. 1 shows a flowchart of a method for reinforcing a bonded wafer.

FIG. 2 shows a flowchart of a method for reinforcing a bonded wafer according to an embodiment of the present invention.

FIG. 3 schematically illustrates a bonded wafer provided in a method for reinforcing a bonded wafer according to an embodiment of the present invention.

FIG. 4 schematically illustrates a structure resulting from an edge grinding process in a method for reinforcing a bonded wafer according to an embodiment of the present invention.

FIG. 5 schematically illustrates a structure resulting from a first selective etching process performed in a method for reinforcing a bonded wafer according to an embodiment of the present invention.

FIG. 6 schematically illustrates a structure resulting from a second selective etching process performed in a method for reinforcing a bonded wafer according to an embodiment of the present invention.

FIG. 7 is a diagram showing nano-scale morphology of a bonded wafer that has been strengthened in Comparative Example I.

FIG. 8 is a diagram showing nano-scale morphology of a bonded wafer that has been strengthened in Comparative Example II.

FIG. 9 is a diagram showing nano-scale morphology of a bonded wafer that has been strengthened in Comparative Example III.

FIG. 10 is a diagram showing nano-scale morphology of a bonded wafer that has been strengthened in Comparative Example IV.

FIG. 11 is a diagram showing nano-scale morphology of a bonded wafer that has been strengthened in Comparative Example V.

In these figures,

10 denotes a substrate layer; 20, a top silicon layer; and 30, an insulating buried oxide layer.

### DETAILED DESCRIPTION

FIG. 1 shows a flowchart of a method for reinforcing a bonded wafer. Referring to FIG. 1, in step S1, the bonded wafer is provided, which includes a substrate layer, a top silicon layer and an insulating buried oxide layer. In this step, the bonded wafer is obtained from an immediately preceding bonding process for forming the bonded wafer. The formation of the bonded wafer may include: performing an oxidation process on the substrate layer and/or the top silicon layer to form oxide layers; and bonding the substrate layer and the top silicon layer together, thereby forming the bonded wafer. The insulating buried oxide layer is provided by an oxide layer between the substrate layer and the top silicon layer and isolates the substrate layer and the top silicon layer from each other. In step S2, a thermal reinforcing process is carried out on the bonded wafer at a temperature higher than 1000° C. to strengthen adhesion of the bonded wafer. In step S3, an edge grinding process is carried out on an unbonded region along the periphery of the top silicon layer. However, in the high-temperature thermal reinforcing process that immediately follows the bonding process, the bonded wafer would be subject to stress on the backside (i.e., the surface of the top silicon layer away from the substrate layer) caused by its own weight, and the greater the weight is, the greater the stress would be. Additionally, the high temperature used in this process (1000° C. or above) would induce significant thermal stress in the bonded wafer. As a consequence, the bonded wafer may deform, so defects may form on the backside and spread to the front side of the bonded wafer (i.e., the surface of the top silicon layer away from the substrate layer), thus forming slip lines on the front side of the bonded wafer.

In view of this, the present invention provides a method for reinforcing a bonded wafer, which includes: providing the bonded wafer, which includes a substrate layer, a top silicon layer and an insulating buried oxide layer; performing a first thermal reinforcing process on the bonded wafer; performing an edge grinding process on an unbonded region along the periphery of the top silicon layer; and performing a second thermal reinforcing process on the bonded wafer at a temperature higher than a temperature at which the first thermal reinforcing process is performed. Thus, according to the present invention, the bonded wafer is subjected to two thermal reinforcing processes, including a first thermal reinforcing process performed at a lower temperature and a second thermal reinforcing process performed at a higher temperature. The first, lower-temperature thermal reinforcing process primarily strengthens adhesion of the bonded wafer to prevent delamination from occurring at the bond interface. The following edge grinding process reduces the weight of the bonded wafer, and the second, higher-temperature thermal reinforcing process additionally strengthens adhesion of the bonded wafer to reduce defects in the bonded wafer, which may develop into slip lines. In this way, the generation of slip lines in the bonded wafer is reduced, increasing yield of products manufactured from the bonded wafer.

Objects, advantages and features of the present invention will become more apparent upon reading the following more detailed description with reference to the accompanying drawings, which illustrate particular embodiments thereof. Note that the figures are provided in a very simplified form not necessarily drawn to exact scale for the only purpose of helping to explain the disclosed embodiments in a more convenient and clearer way. In addition, the illustrated structures are usually part of their real-world counterparts. In particular, as the figures tend to have distinct emphases, they are sometimes drawn to different scales.

As used herein, the singular forms “a”, “an” and “the” include plural referents, and the term “or” is generally employed in the sense of “and/or”, “a number of” of “at least one”, and “at least two” of “two or more”. Additionally, the use of the terms “first”, “second” and “third” herein is intended for illustration only and is not to be construed as denoting or implying relative importance or as implicitly indicating the numerical number of the referenced items. Accordingly, defining an item with “first”, “second” or “third” is an explicit or implicit indication of the presence of one or at least two such items. The terms “one end” and “other end” may be used herein to generally refer to two opposite portions. Those of ordinary skill in the art can understand the specific meanings of the above-mentioned terms herein, depending on their context.

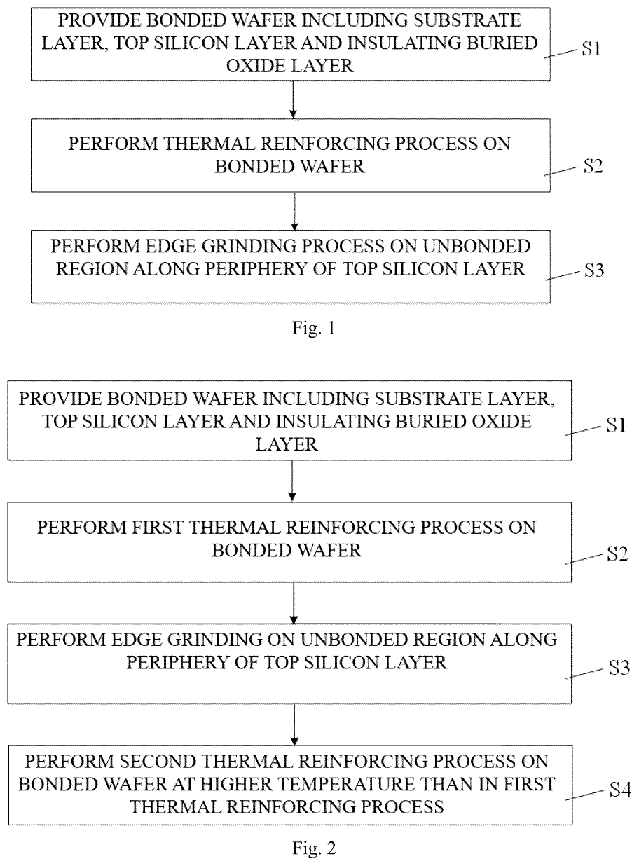

FIG. 2 shows a flowchart of a method for reinforcing a bonded wafer according to embodiments of the present invention, which, as shown in FIG. 2, includes the steps of:
S1) providing the bonded wafer, which includes substrate layer, a top silicon layer and an insulating buried oxide layer;
S2) performing a first thermal reinforcing process on the bonded wafer;
S3) performing an edge grinding process on an unbonded region along the periphery of the top silicon layer; and
S4) performing a second thermal reinforcing process on the bonded wafer at a temperature higher than a temperature at which the first thermal reinforcing process is performed.

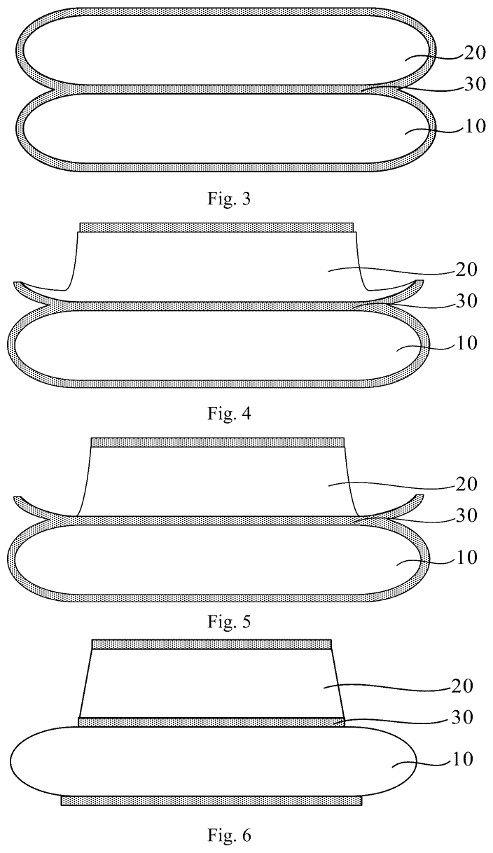

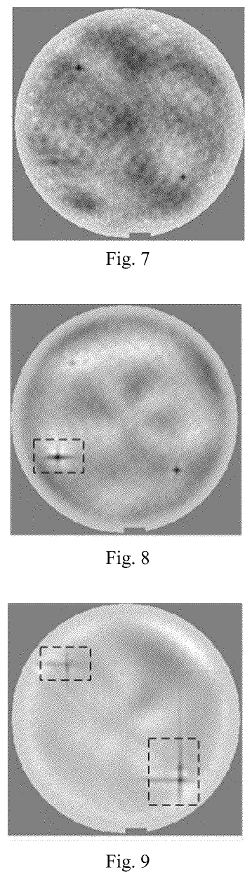

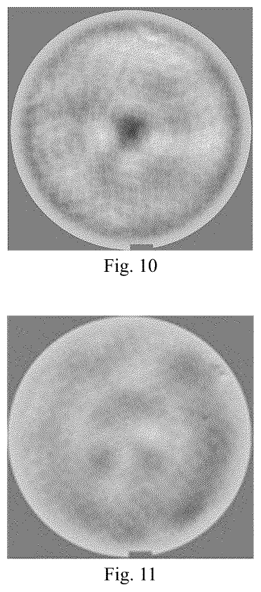

FIG. 3 schematically illustrates a bonded wafer provided in a method for reinforcing a bonded wafer according to an embodiment of the present invention. FIG. 4 schematically illustrates a structure resulting from an edge grinding process performed in a method for reinforcing a bonded wafer according to an embodiment of the present invention. FIG. 5 schematically illustrates a structure resulting from a first selective etching process performed in a method for reinforcing a bonded wafer according to an embodiment of the present invention. FIG. 6 schematically illustrates a structure resulting from a second selective etching process performed in a method for reinforcing a bonded wafer according to an embodiment of the present invention. FIG. 7 is a diagram showing nano-scale morphology of a bonded wafer that has been strengthened in Comparative Example I. FIG. 8 is a diagram showing nano-scale morphology of a bonded wafer that has been strengthened in Comparative Example II. FIG. 9 is a diagram showing nano-scale morphology of a bonded wafer that has been strengthened in Comparative Example III. FIG. 10 is a diagram showing nano-scale morphology of a bonded wafer that has been strengthened in Comparative Example IV. FIG. 11 is a diagram showing nano-scale morphology of a bonded wafer that has been strengthened in Comparative Example V. The invention will be described in greater detail below with reference to FIGS. 3 to 11.

In step S1, referring to FIG. 3, a bonded wafer is provided, which includes substrate layer 10, a top silicon layer 20 and an insulating buried oxide layer 30. The bonded wafer provided in this step is obtained from an immediately preceding bonding process, and is intended to be subjected to subsequent steps including thermal reinforcing, filleting and polishing. The formation of the bonded wafer may include the steps of: performing an oxidation process on the substrate layer 10 and/or the top silicon layer 20 to form oxide layers (in the case of FIG. 3, the oxidation process is performed on both the substrate layer 10 and the top silicon layer 20, and as a result of the process, the substrate layer 10 and the top silicon layer 20 is each encapsulated by an oxide layer); and bonding the substrate layer 10 and the top silicon layer 20 together, thereby forming the bonded wafer. The insulating buried oxide layer 30 is provided by an oxide layer between the substrate layer 10 and the top silicon layer 20 and isolates the substrate layer 10 and the top silicon layer 20 from each other. In one embodiment, each of the substrate layer 10 and the top silicon layer 20 may have a diameter of 200 mm, 300 mm or 450 mm and a thickness of 773 μm to 777 μm. A thickness difference between the substrate layer 10 and the top silicon layer 20, as defined as the difference between maximum and minimum thicknesses, may be less than 0.5 μm. The insulating buried oxide layer 30 may have a thickness greater than 0.5 μm and less than 2 μm. The specific values of these parameters are illustrative and do not limit the present invention in any sense. The substrate layer 10 is preferred to be a silicon layer, and the insulating buried oxide layer 30 is preferred to be a silicon dioxide layer.

In step S2, the resulting bonded wafer is subjected to a first thermal reinforcing process. In order to prevent this first thermal reinforcing process from inducing significant thermal stress and hence possibly deformation of the bonded wafer due to an excessively high temperature (e.g., 1000° C. or higher), the thermal reinforcing process is desirably carried out at a temperature lower than or equal to 1000° C. In a non-limiting embodiment, the first thermal reinforcing process is performed at a preferred temperature of 850° C. to 1000° C. for a preferred period of time of 30 min to 120 min in a preferred oxygen-containing or hydrogen-containing inert atmosphere (e.g., an Ar, N₂ or He atmosphere). Since the first thermal reinforcing process is performed on the resulting bonded wafer at a relatively low temperature (e.g., lower than or equal to 1000° C.), it can strengthen adhesion of the bonded wafer and prevent delamination from occurring at the bond interface, without inducing significant thermal stress which may cause deformation of the bonded wafer.

In step S3, referring to FIG. 4, an edge grinding process is carried out on an unbonded region along the periphery of the top silicon layer 20. Before the substrate layer 10 and the top silicon layer 20 are bonded to each other, they may have been peripherally rounded by experiencing separate peripheral filleting processes for preventing broken edges due to subsequent collisions, resulting in a gap between them (and hence the unbonded region) along the periphery after the bonding process. Therefore, the unbonded region refers to a (peripheral) region, where the substrate layer 10 and the top silicon layer 20 remains not bonded to each other. In the unbonded region, a partial thickness may survive the edge grinding process so that the bottom layer in the bonded wafer remains unpolished even when the polishing process has failed to be conducted in an even style. In one embodiment, the thickness retained in the unbonded region from the polishing process is 20 μm. As a result of the edge grinding process, the weight of the bonded wafer is reduced due to material loss in the peripheral region.

After the edge grinding process is completed, the method may further include, as shown in FIG. 5, performing a first selective etching process to remove the top silicon layer 20 remaining in the unbonded region, exposing the underlying insulating buried oxide layer 30 using a mixed acid solution as an etchant (which may include hydrofluoric acid, sulfuric acid, nitric acid and phosphoric acid). The first selective etching process may stop at the surface of the insulating buried oxide layer 30 (and the previously covered portion of the insulating buried oxide layer 30 is therefore exposed). The first selective etching process may be a (isotropic) wet etching process, which may also laterally proceed in the top silicon layer 20 to a certain extent. Referring to FIG. 6, a second selective etching process may follow the first selective etching process to remove the insulating buried oxide layer 30 exposed from the top silicon layer 20 and stop at the surface of the substrate layer 10. The second selective etching process may use hydrofluoric acid as an etchant, and due to fluidity of the hydrofluoric acid, the oxide layer overlying the sides and bottom of the substrate layer 10 along the periphery may be concurrently removed, in addition to the exposed insulating buried oxide layer 30. In each of the first and second selective etching processes, the etchant may be sprayed from a nozzle onto a specified portion of the bonded wafer, which is being suspended. Generally, the second selective etching process does not affect the insulating buried oxide layer 30 aligned with the central portions of the underlying substrate layer 10 and the overlying top silicon layer 20. As a result of the two selective etching processes, the bonded wafer may be almost free of defects in the peripheral region. This can avoid unwanted conditions such as broken edges in the subsequent grinding, polishing and similar processes.

In step S4, a second thermal reinforcing process is performed on the bonded wafer at a temperature higher than that in the first thermal reinforcing process. The second thermal reinforcing process may be performed at a temperature higher than 1000° C. In a non-limiting embodiment, the second thermal reinforcing process is performed at a preferred temperature of 1100° C. to 1300° C. for a preferred period of time of 30 min to 150 min in a preferred oxygen-containing or hydrogen-containing inert atmosphere (e.g., an Ar, N₂ or He atmosphere). Since the bonded wafer has undergone a weight loss in the edge grinding process, it is subject to reduced stress on the backside (i.e., the surface of the substrate layer away from the top silicon layer) and hence less thermal stress induced by the higher temperature (e.g., above 1000° C.) in the second thermal reinforcing process. Therefore, defects are less likely to form on the backside of the bonded wafer, which may otherwise spread through the bonded wafer from the backside to the front side thereof (i.e., the surface of the top silicon layer away from the substrate layer) as the high-temperature reinforcing process proceeds and thereby develop into slip lines. Thus, the second thermal reinforcing process that follows the edge grinding process can not only additionally strength adhesion of the bonded wafer, but can also reduce the generation of slip lines in the bonded wafer, improving yield of products manufactured from the bonded wafer. Further, the second thermal reinforcing process that follows the edge grinding process provides heat treatment capable of repairing possible damage arising from polishing actions in the edge grinding process. The second thermal reinforcing process that follows the two selective etching processes also provides heat treatment capable of repairing damage possibly caused by the selective etching processes.

Comparative examples are set forth below to further explain the present invention.

In a first comparative example (referred to hereinafter as “Comparative Example I”), a bonded wafer was provided, which included substrate layer, a top silicon layer and an insulating buried oxide layer. The substrate layer and the top silicon layer were each 775-μm thick and had a thickness difference less than 0.5 μm. A first thermal reinforcing process was carried out on the bonded wafer at 950° C. for 60 min in an oxygen-containing inert atmosphere. An edge grinding process was performed on an unbonded region along the periphery of the top silicon layer, and a second thermal reinforcing process was then carried out on the bonded wafer at 1200° C. for 60 min in an oxygen-containing inert atmosphere.

In a second comparative example (referred to hereinafter as “Comparative Example II”), a bonded wafer was provided, which included substrate layer, a top silicon layer and an insulating buried oxide layer. The substrate layer and the top silicon layer were each 775-μm thick and had a thickness difference less than 0.5 μm. A first thermal reinforcing process was carried out on the bonded wafer at 1050° C. for 60 min in an oxygen-containing inert atmosphere. An edge grinding process was performed on an unbonded region along the periphery of the top silicon layer, and a second thermal reinforcing process was then carried out on the bonded wafer at 1200° C. for 60 min in an oxygen-containing inert atmosphere. As can be seen, Comparative Example II differs from Comparative Example I in terms of the temperature of the first thermal reinforcing process.

In a third comparative example (referred to hereinafter as “Comparative Example III”), a bonded wafer was provided, which included substrate layer, a top silicon layer and an insulating buried oxide layer. The substrate layer and the top silicon layer were each 775-μm thick and had a thickness difference less than 0.5 μm. A first thermal reinforcing process was carried out on the bonded wafer at 1100° C. for 60 min in an oxygen-containing inert atmosphere. An edge grinding process was performed on an unbonded region along the periphery of the top silicon layer, and a second thermal reinforcing process was then carried out on the bonded wafer at 1200° C. for 60 min in an oxygen-containing inert atmosphere. As can be seen, Comparative Example III differs from Comparative Examples I and II in terms of the temperature of the first thermal reinforcing process.

In a fourth comparative example (referred to hereinafter as “Comparative Example IV”), a bonded wafer was provided, which included substrate layer, a top silicon layer and an insulating buried oxide layer. The substrate layer and the top silicon layer were each 775-μm thick and had a thickness difference less than 0.5 μm. A first thermal reinforcing process was carried out on the bonded wafer at 850° C. for 60 min in an oxygen-containing inert atmosphere. An edge grinding process was performed on an unbonded region along the periphery of the top silicon layer, and a second thermal reinforcing process was then carried out on the bonded wafer at 1200° C. for 60 min in an oxygen-containing inert atmosphere. As can be seen, Comparative Example IV differs from Comparative Examples I, II and III in terms of the temperature of the first thermal reinforcing process.

In a fifth comparative example (referred to hereinafter as “Comparative Example V”), a bonded wafer was provided, which included substrate layer, a top silicon layer and an insulating buried oxide layer. The substrate layer and the top silicon layer were each 775-μm thick and had a thickness difference less than 0.5 μm. A first thermal reinforcing process was carried out on the bonded wafer at 800° C. for 60 min in an oxygen-containing inert atmosphere. An edge grinding process was performed on an unbonded region along the periphery of the top silicon layer, and a second thermal reinforcing process was then carried out on the bonded wafer at 1200° C. for 60 min in an oxygen-containing inert atmosphere. As can be seen, Comparative Example V differs from Comparative Examples I, II, III and IV in terms of the temperature of the first thermal reinforcing process.

FIG. 7 is a diagram showing nano-scale morphology of the front side of the bonded wafer of Comparative Example I. As can be seen, no slip lines are observed, demonstrating that defects, and hence slip lines which may develop therefrom, in the bonded wafer can be reduced, improving yield of products manufactured from the bonded wafer, through first reinforcing adhesion of the bonded wafer and hence preventing subsequent delamination at the bond interface using the first, low-temperature (950° C.) thermal reinforcing process, then reducing the weight of the bonded wafer by the edge grinding process and finally additionally strength adhesion of the bonded wafer using the second higher-temperature (1200° C.) thermal reinforcing process.

FIG. 8 is a diagram showing nano-scale morphology of the front side of the bonded wafer of Comparative Example II. As can be seen, obvious slip lines (as indicated by the dashed boxed in the figure) are observed, demonstrating that the first thermal reinforcing process performed at a temperature higher than 1000° C. (e.g., 1050° C.) may cause defects on the backside of the bonded wafer, which may then spread through the bonded wafer to the front side thereof as the high-temperature process proceeds, thus forming slip lines on the front side of the bonded wafer.

FIG. 9 is a diagram showing nano-scale morphology of the front side of the bonded wafer of Comparative Example III. As can be seen, obvious slip lines (as indicated by the dashed boxed in the figure) are observed, demonstrating that the first thermal reinforcing process performed at a temperature higher than 1000° C. (e.g., 1100° C.) may cause defects on the backside of the bonded wafer, which may then spread through the bonded wafer to the front side thereof as the high-temperature process proceeds, thus forming slip lines on the front side of the bonded wafer.

FIG. 10 is a diagram showing nano-scale morphology of the front side of the bonded wafer of Comparative Example IV. As can be seen, no slip lines are observed, demonstrating that defects, and hence slip lines which may develop therefrom, in the bonded wafer can be reduced, improving yield of products manufactured from the bonded wafer, through first reinforcing adhesion of the bonded wafer and hence preventing subsequent delamination at the bond interface using the first, low-temperature (850° C.) thermal reinforcing process, then reducing the weight of the bonded wafer by the edge grinding process and finally additionally strength adhesion of the bonded wafer using the second higher-temperature (1200° C.) thermal reinforcing process.

FIG. 11 is a diagram showing nano-scale morphology of the front side of the bonded wafer of Comparative Example V. Although no slip lines are observed in FIG. 11, there is a risk of subsequent delamination at the bond interface.

The results of Comparative Examples I, II, III, IV and V show that, in order to prevent the formation of slip lines on the front side of the bonded wafer, it is particularly important to perform the first thermal reinforcing process at a temperature lower than 1000° C. (preferably, at a temperature of 850° C. to 1000° C.). The edge grinding process can reduce the weight of the bonded wafer, and the second thermal reinforcing process performed at a higher temperature can additionally strength adhesion of the bonded wafer and reduce defects therein.

In summary, the present invention provides a method for reinforcing a bonded wafer, including: providing the bonded wafer, which includes a substrate layer, a top silicon layer and an insulating buried oxide layer; performing a first thermal reinforcing process on the bonded wafer; performing an edge grinding process on an unbonded region along the periphery of the top silicon layer; and performing a second thermal reinforcing process on the bonded wafer at a temperature higher than a temperature at which the first thermal reinforcing process is performed. Thus, according to the present invention, the bonded wafer is subjected to two thermal reinforcing processes, including a first thermal reinforcing process performed at a lower temperature and a second thermal reinforcing process performed at a higher temperature. The first, lower-temperature thermal reinforcing process primarily strengthens adhesion of the bonded wafer to prevent delamination from occurring at the bond interface. The following edge grinding process reduces the weight of the bonded wafer, and the second, higher-temperature thermal reinforcing process additionally strengthens adhesion of the bonded wafer to reduce defects in the bonded wafer, which may develop into slip lines. In this way, the generation of slip lines in the bonded wafer is reduced, increasing yield of products manufactured from the bonded wafer.

Presented above are merely a few preferred embodiments of the present invention, which do not limit the invention in any way. Changes in any forms made to the principles and teachings disclosed herein, including equivalents and modifications, by any person of ordinary skill in the art without departing from the scope of the invention are intended to fall within the scope of the invention.

1. A method for reinforcing a bonded wafer, comprising:
providing the bonded wafer, which comprises a substrate layer, a top silicon layer and an insulating buried oxide layer;
performing a first thermal reinforcing process on the bonded wafer;
performing an edge grinding process on an unbonded region along the periphery of the top silicon layer; and
performing a second thermal reinforcing process on the bonded wafer at a temperature higher than a temperature at which the first thermal reinforcing process is performed.

2. The method of claim 1, wherein the temperature at which the first thermal reinforcing process is performed is lower than or equal to 1000° C.

3. The method of claim 2, wherein the temperature at which the first thermal reinforcing process is performed ranges from 850° C. to 1000° C.

4. The method of claim 2, wherein the first thermal reinforcing process is performed for a period of time ranging from 30 min to 120 min.

5. The method of claim 1, wherein the temperature at which the second thermal reinforcing process is performed is higher than 1000° C.

6. The method of claim 5, wherein the temperature at which the second thermal reinforcing process is performed ranges from 1100° C. to 1300° C.

7. The method of claim 5, wherein the second thermal reinforcing process is performed for a period of time ranging from 30 min to 150 min.

8. The method of claim 1, wherein each of the first thermal reinforcing process and the second thermal reinforcing process is performed in an oxygen-containing or hydrogen-containing inert atmosphere.

9. The method of claim 1, wherein after the edge grinding process, the method further comprises performing a first selective etching process to remove the top silicon layer remaining in the unbonded region, exposing the underlying insulating buried oxide layer.

10. The method of claim 9, wherein after the first selective etching process and before performing the second thermal reinforcing process, the method further comprises performing a second selective etching process to remove the insulating buried oxide layer exposed from the top silicon layer and stop at a surface of the substrate layer.

11. The method of claim 9, wherein the first selective etching process uses a mixed acid solution as an etchant, the mixed acid solution comprises hydrofluoric acid, sulfuric acid, nitric acid and phosphoric acid.

12. The method of claim 10, wherein the second selective etching process uses hydrofluoric acid as an etchant.
